(19) United States
(12) Patent Application Publication
(10) Pub. No.: US 2012/0304773 A1
(43) Pub. Date: Dec. 6, 2012

(54) ESTIMATION OF PRESENCE OF VOID IN THROUGH SILICON VIA (TSV) BASED ON ULTRASOUND SCANNING

(75) Inventors: Akihiro Horibe, Kanagawa-ken (JP); Fumiaki Yamada, Kanagawa-ken (JP)

(73) Assignee: International Business Machines Corporation, Armonk, NY (US)

(21) Appl. No.: 13/484,347

(22) Filed: May 31, 2012

(30) Foreign Application Priority Data
Jun. 2, 2011 (JP) 2011-124548

(51) Int. Cl. G01N 29/04; H01L 23/48

(52) U.S. Cl. 73/618; 257/48; 257/E23.011

(57) ABSTRACT

A method and apparatus to detect a defect in a three-dimensional integrated structure by ultrasound scanning and to non-destructively detect the presence of a void that can occur in a process in a through silicon via (TSV) arranged in a board, such as a silicon wafer. To avoid measurement by ultrasound scanning over a board surface from being impeded by an object, such as a (solder) bump, scattering ultrasound, one or more TSVs belonging to a test element group (TEG) are selected from among a plurality of TSVs such that physical obstruction in the vicinity of the TEG.

### CROSS-REFERENCE TO RELATED APPLICATION

This application claims priority under 35 U.S.C. §119 from Japanese Patent Application No. 2011-124548 filed Jun. 2, 2011, the entire contents of which are incorporated herein by reference.

### BACKGROUND OF THE INVENTION

1. Field of the Invention

The present invention relates to a technique for detecting a defect in a three-dimensional integrated structure by ultrasound scanning, and more specifically, it relates to non-destructive detection of the presence of a void that can occur in a process in a through silicon via (TSV) arranged in a board.

2. Description of Related Art

A three-dimensional integration technology using through silicon vias (TSVs) needs a technique for non-destructively detecting a defect in a TSV at an early stage in a process. One known method for producing a TSV is a “via last technique.” A through silicon via (TSV) can also be simply called “via.”

FIG. 1 illustrates a general outline of processes in the via last technique. In rough classification, a via first technique and a via middle technique belong to a group in which a via is created before completion of a device and a wiring layer. In contrast, the via last technique is one in which a via is created in a subsequent process, as indicated by its name.

In Process 1, a semiconductor board, such as a silicon wafer, is prepared. The board includes a device surface side and a non-device surface side. A thin aluminum (or possibly copper; the same applies to the following) layer having a thickness of approximately 1 μm is prepared on the device-surface side. A device, a wiring layer, and other elements have already been formed in the aluminum layer.

FIG. 2 illustrates a partly enlarged aluminum layer. As illustrated in FIG. 2, the aluminum layer can include aluminum wiring layers as metal layers M1 to M7, for example, in which a plurality of semiconductor devices and wiring for coupling them are prepared. An aluminum pad is prepared on a TSV or in the vicinity thereof, and a bump (typically solder bump) is prepared on the aluminum pad (below it in FIG. 2). The aluminum layer also functions as an etching stop layer in subsequent formation of a TSV indicated by the dot lines. Referring back to FIG. 1, in Process 2, the board is bonded to a support substrate, such as one made from glass, with an adhesive.

In Process 3, the supported board is grinded and made thinner. Although the thickness of the illustrated board is exaggerated, the actual board is made very thin. Thus the board is required to be supported by the support substrate because the rigidity of the board itself is low. In the case of a method called “back via (method)” in the via last technique, the board is made thin before a TSV is formed, as illustrated in Process 3.

FIG. 3 illustrates processes for forming a through silicon via (TSV). In Process 4, a through hole that reaches the aluminum layer is formed by, for example, dry etching. The aluminum layer also functions as the etching stop layer, as previously described. The through hole is referred to as so because it penetrates through the board; it is in a “recess” or “hole” state in that one opening of the hole is blocked by the aluminum layer.

In Process 5, an insulating layer (for providing electrical isolation between the board and the via) is formed on the inside of the through hole, and the insulating layer being in contact with the aluminum layer (in the bottom of the via) is removed. After that, thin-film layers, such as a barrier layer (for preventing diffusion to silicon, which is the material of the board, or other elements) and a seed layer (for use in transmitting electricity) are formed.

In Process 6, the through hole is filled with a conductive metal material, such as copper (Cu), by a process, such as plating, from the opening (the non-device surface side). For a successful example illustrated on the left side in the drawing, the plating reaches the aluminum layer. In contrast, for an unsuccessful example illustrated on the right side in the drawing, the plating material is not sufficiently spread and does not reach the aluminum layer, and a void (gap) occurs.

The void occurs because of an imperfection of a solution in the plating process or the like. Such a defective mode impedes conduction between the etching stop layer and the metal of the TSV and makes the TSV inactive. To make matters worse, because the opening of the board is covered, such a void is hidden, cannot be sought in a surface inspection, and remains as a defect.

If the depth of a through hole is much greater than the diameter (approximately 5 μm at the minimum), for example, the ratio of the diameter to the depth is 1 to 2 or more, the plating solution or copper ions in the plating solution cannot reach the deep area (etching stop layer), and the unfilled area can remain as a gap.

The seed layer (path of electricity during plating) for use in electroplating is typically formed by sputtering (discharging electricity in a vacuum and depositing ejected metal atoms or clusters). If the seed layer is imperfect and a sufficient electric current is not transmitted to a deep area, this can cause a void.

Referring back to FIG. 1, in Process 7, the support substrate is separated. In Process 8, the adhesive is removed. If an internal defect can be detected by a high-speed, non-contact, and non-destructive inspection performed over the entire wafer surface at an early process stage immediately after the plating process, such as in Process 7 or 8, the manufacturing cost can be significantly reduced. However, a satisfactory method for detecting a void that remains hidden in small-diameter TSVs arranged at a narrow pitch has not been known yet.

An X-ray inspection known as an existing method requires a very long time for capturing an image. Thus, inspecting the entire surface is impractical from a cost standpoint. With an X-ray inspection, if a gap is small in a projection direction, the gap can be undetectable.

In theory, the presence of a void is observable with a C-mode scanning acoustic microscope (C-SAM) having a high resolution. However, typically, because a bump electrode or a wiring layer is present directly above or below the void in the TSV and the wiring and the bump shape on the surface layer as “physical obstruction” scatters ultrasound, it is difficult to detect a void with a ultrasonic microscope using echoes of an ultrasonic wave.

Japanese Patent Application Publication No. 2000-82121 describes detecting and reading a barcode in an information card by the use of ultrasound with a high frequency, the location where the barcode is embedded in the information card being unknown from the surface. However, the disclosed technique does not deal with estimating the presence of a void in a through silicon via (TSV) and, in addition, Japanese Patent Application Publication No. 2000-82121 has no discussion of a test element group (TEG) having less physical obstruction.

It is an object of the present invention to solve the above-described problem, which remains unsolved in the background art. In the present invention, to detect the presence or absence of a hidden void in TSVs, a test element group (TEG) region where only an etching stop layer and one or more TSVs are disposed is formed in a location where a structure (bump electrode or wiring layer) that decreases a resolving power is not disposed directly above or below the TSVs to be detected, such as in the vicinity of a chip, and the presence or absence of the hidden void in the TSVs is detected and estimated by the use of an ultrasonic microscope.

In particular, in the case of an observation of minute TSVs, which requires high resolution, it is necessary to perform observation with a small observation distance to a defect by the use of an ultrasonic probe having a high numerical aperture (NA) and it is preferable that the observation be made from a semiconductor device surface. For this inspection and estimation method using a TEG, the accuracy of estimation is improved by simultaneously forming, in addition to TSVs having the same diameter as in an active TSV, TSVs that are narrower by, for example, approximately 10%, 20%, or 40% at the same time, as TSVs arranged in the TEG.

In terms of the density of TSVs, in addition to TSVs arranged at the same pitch as the minimum pitch of active TSVs, TSVs arranged at a pitch that is smaller by, for example, 10% or 20% are formed at the same time. The TEG is arranged in at least one location in the chip surface; in particular, for a wafer in which neighboring chips have different TSV patterns, in consideration of differences in plating rates resulting from the arrangement of chips in the wafer surface, one or more TEGs are positioned on each of both sides of the border between the different chips.

Appropriately specifying the shape of a TSV and the pitch of TSVs arranged in a TEG and the location of the TEG in a chip enables the detection accuracy in estimation of the occurrence of a void over the entire surface of a wafer can to be improved and thus enables the occurrence of a defect in an active TSV in a chip to be materially estimated with high sensitivity.

### SUMMARY OF THE INVENTION

In a first aspect of the invention, a method for estimating a presence of a void in a through silicon via (TSV) on the basis of ultrasound scanning is provided. The method includes preparing a board in which a plurality of TSVs are arranged, selecting one or more TSVs belonging to a test element group (TEG) from among the plurality of TSVs, where physical obstruction in a vicinity of the TEG being less than the physical obstruction in a vicinity of other TSVs that do not belong to the TEG in scanning over a board surface, scanning at least one of the one or more TSVs belonging to the TEG over the board surface and estimating that a void is present in the other TSVs not belonging to the TEG on the basis of a result of the scanning.

In a second aspect of the invention, a board is provided. The board includes a plurality of through silicon vias (TSVs) which are arranged to estimate a presence of a void in the TSVs, where one or more TSVs belonging to a test element group (TEG) are selected from among the plurality of TSVs, and physical obstruction in a vicinity of the one or more TSVs being less than the physical obstruction in a vicinity of other TSVs not belonging to the TEG in scanning on a board surface.

In a third aspect of the invention, an apparatus for estimating a presence of a void in a through silicon via (TSV) on the basis of ultrasound scanning is provided. The apparatus includes a display, an imaging processing unit, a computation processing unit, a control circuit, an AD/DA conversion unit, a transmission unit, a receiving unit, a prepared board in which a plurality of TSVs are arranged, where one or more TSVs belonging to a test element group (TEG) from among the plurality of TSVs, and physical obstruction in a vicinity of the TEG being less than physical obstruction in a vicinity of other TSVs that do not belong to the TEG in scanning over a board surface.

### BRIEF DESCRIPTION OF THE DRAWINGS

FIG. 1 illustrates a general outline of processes in a via last technique.

FIG. 2 illustrates a partly enlarged aluminum layer.

FIG. 3 illustrates processes for forming a through silicon via (TSV).

FIG. 4 illustrates a basic principle of a method for estimating the presence of a void in a through silicon via (TSV) on the basis of ultrasound scanning according to the present invention.

FIG. 5 is a schematic diagram that illustrates an example of a sonogram obtained as a result of scanning over a board surface.

FIG. 6 is an illustration for describing a principle of focusing an ultrasonic wave on a board using an acoustic lens.

FIG. 7 is a block diagram of an ultrasonic reading system including an ultrasonic reader as the main component.

FIG. 8 is a schematic diagram that illustrates scanning using a single probe.

FIG. 9 is a schematic diagram that illustrates an ultrasonic reception unit achieved by an array of piezoelectric elements.

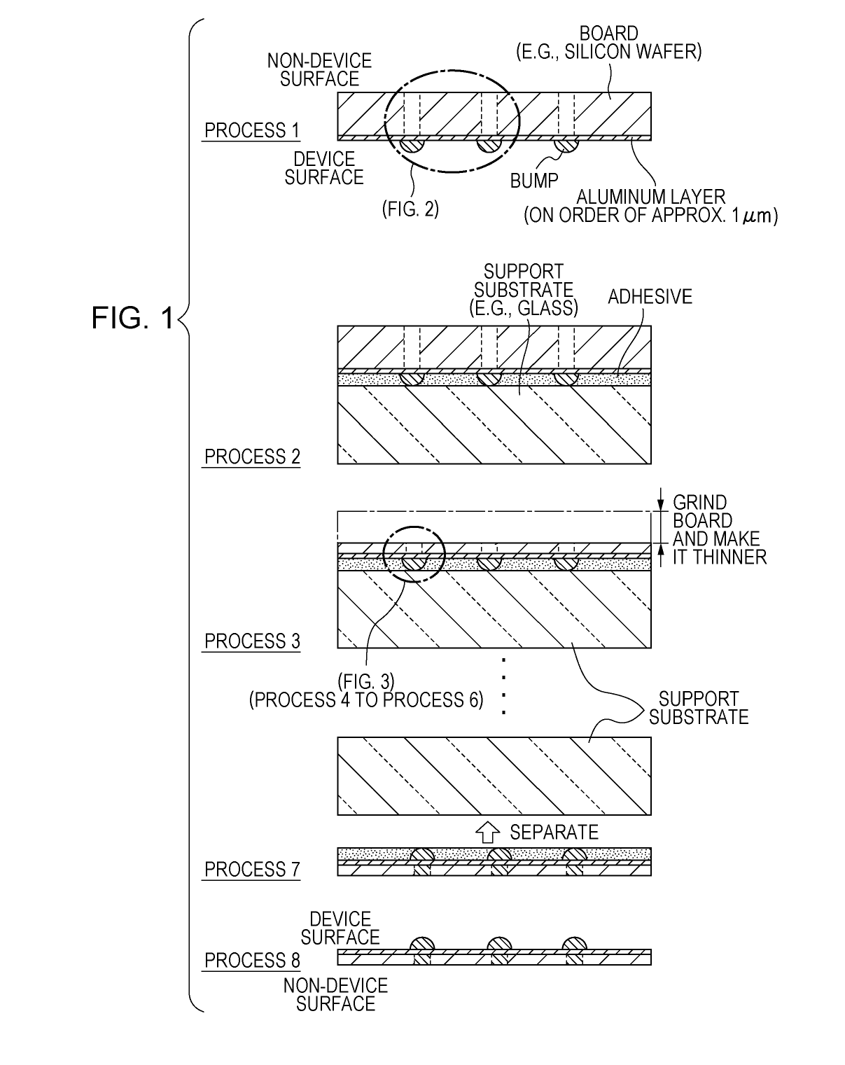

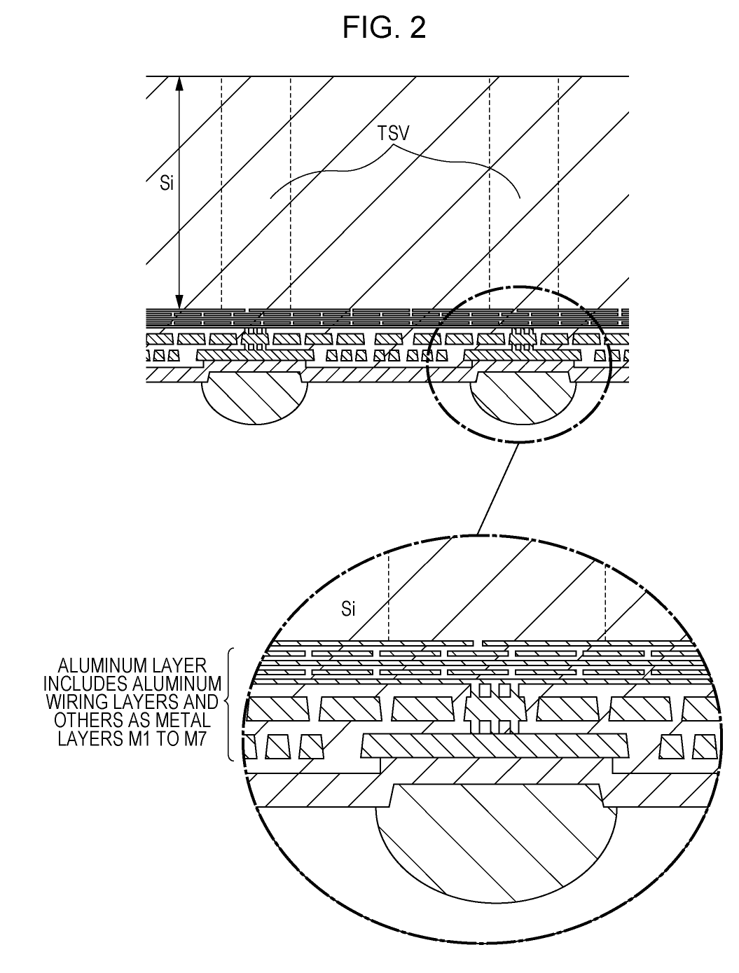

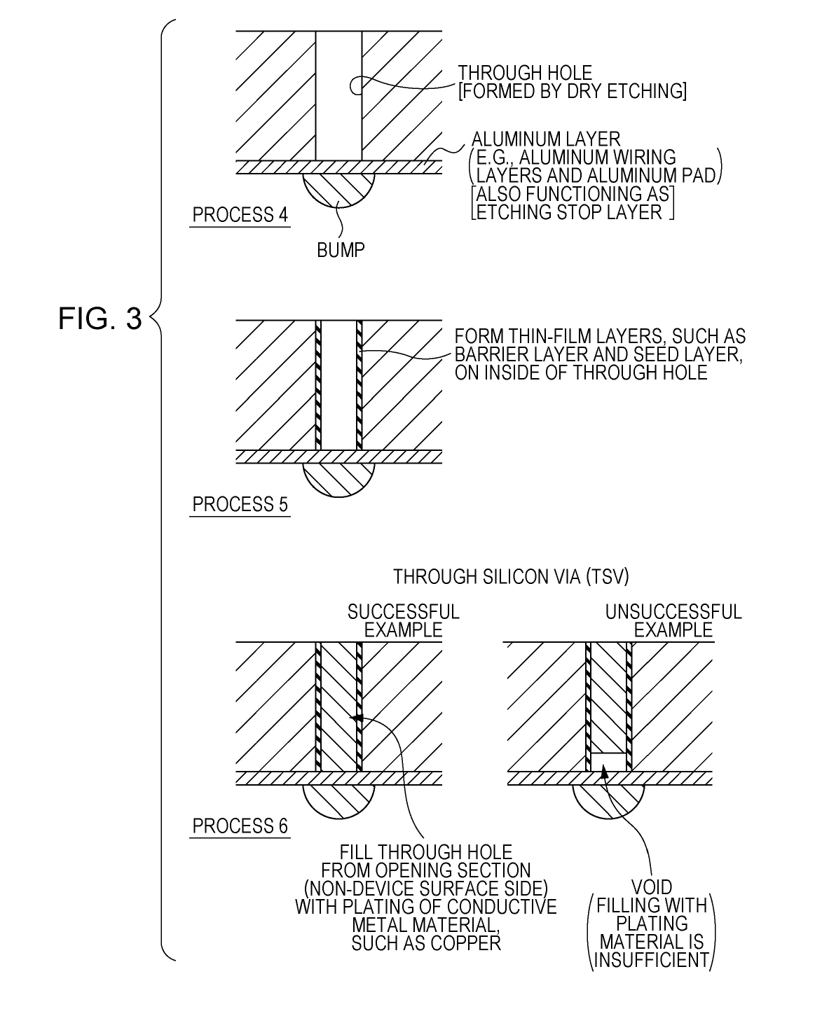

### DETAILED DESCRIPTION OF THE PREFERRED EMBODIMENTS

It should be understood that “ultrasound” or “ultrasonic wave” is a sound that is generally inaudible and that has a frequency of 20 kHz or more, and it is used in various technical applications, such as medical ultrasonic echo equipment, cleaners, fishfinders, and back sonar. In the embodiments of the present invention, it is assumed that a wave having a frequency of 20 kHz or more is used. In some cases, a pulsed wave containing wave components of different frequencies can be used.

The term “scanning” is movement of a location or space to be detected. In the present invention, it is moved over a two-dimensional range indicated by the XY directions or over a three-dimensional range indicated by the XYZ directions.

A first property of ultrasound is that the propagation velocity is significantly lower than that of a radio wave or other electromagnetic waves. The propagation velocity of ultrasound in a solid is higher than that in a liquid, the propagation velocity of ultrasound in a liquid is higher than that in the air, and the medium through which ultrasound propagates has a large influence. The propagation velocity of ultrasound in the air is approximately one fifteenth of an ultrasound velocity in a solid. The propagation velocity v is not dependent on the frequency of the sound and is determined by the ratio between the density of a target substance and the modulus of elasticity thereof, i.e., determined by the following Expression (1):

Propagation velocity v (m/s)=√Modulus of Elasticity (Pa)/Density (kg/m³) (1)

A second property of ultrasound is that it is easily reflected. For example, ultrasound does not pass through glass. Such reflection results from a change in acoustic impedance caused by the difference in density and is based on the nature that ultrasound does not pass through but is reflected at the border between propagation media having significantly different acoustic impedances (density ρ of propagation medium x propagation velocity v).

A third property of ultrasound is that the directivity and the attenuation increase with an increase in frequency. The sharpness of the directivity increases with an increase in the area of the vibration surface with respect to the wavelength and with a reduction in the wavelength.

A fourth property of ultrasound is that there have been no reports that ultrasound harms human bodies and it is deemed to be safe in principle. In practice, ultrasonographic examination is indispensable in today's obstetrics and gynecology. Unlike X-ray examination or other examinations, ultrasonographic examination is deemed to be a safe examination method that poses no risks to a fetus. Ultrasound examination is widely used in cardiac and abdominal diagnosis and in pediatrics.

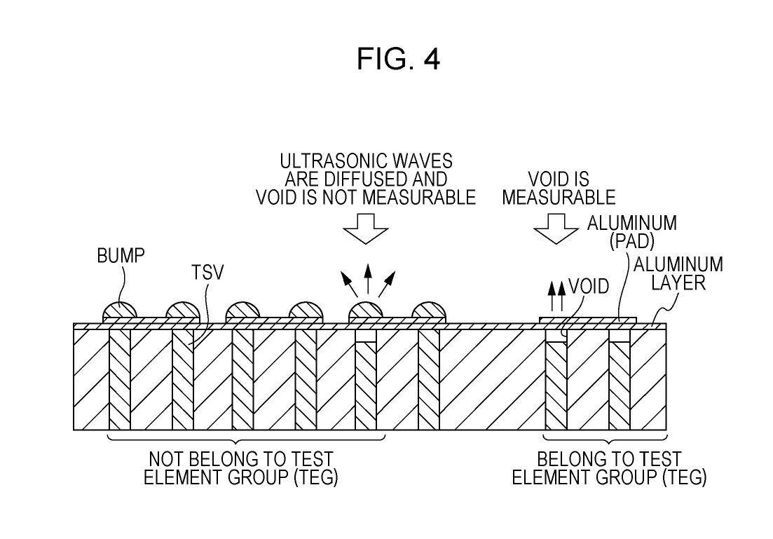

FIG. 4 illustrates a basic principle of a method for estimating the presence of a void in a through silicon via (TSV) on the basis of ultrasound scanning according to the present invention.

To estimate the presence of a void in a board in which a plurality of TSVs are arranged, ultrasound scanning is performed over the board surface. However, in this example, (solder) bumps as physical obstruction scatter ultrasound and impede measurement by ultrasound scanning.

In order to perform ultrasound scanning over the board surface, one or more TSVs belonging to a test element group (TEG) are selected from among the plurality of TSVs such that physical obstruction in the vicinity of the TEG is less than that in the vicinity of other TSVs that do not belong to TEG.

This way of selecting one or more TSVs of a TEG can be designed in advance in the board. The selection can be made while a selection object is flexibly changed, as a mechanical processing step or operation, such as selection made by an apparatus that carries out the selection automatically (or can wait for an instruction from a user and start processing in response to the instruction; the same applies to the following).

Scanning can be performed on at least one TSV belonging to a TEG over the board surface, and it can be estimated on the basis of a result of the scanning that a void is present in other TSVs that do not belong to the TEG. The estimation can be carried out while flexible changes are made, as a mechanical processing step or operation, such as estimation automatically made by an apparatus.

Even if a TEG in which physical obstruction is less is designed in advance in the board, a TSV around which there is much physical obstruction can be inspected on purpose subsequently flexibly.

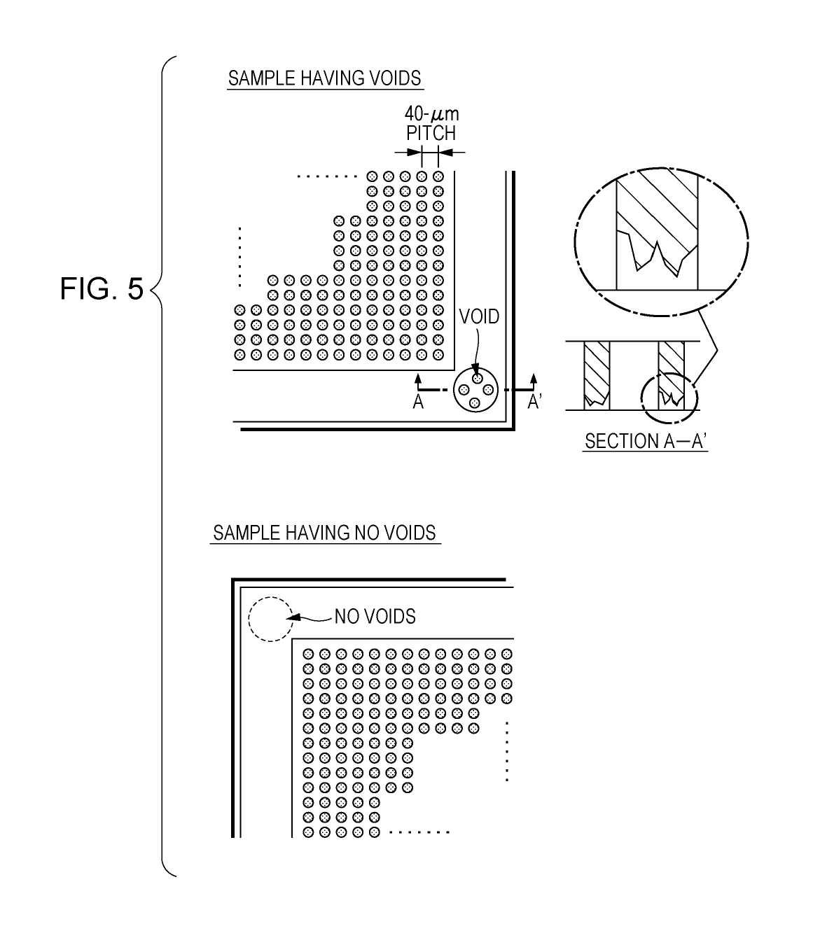

FIG. 5 is a schematic diagram that illustrates an example of a sonogram obtained as a result of scanning over a board surface.

A test element group (TEG) is disposed at the location indicated by the circle of the solid lines or dot lines in the board independently of other TSVs arranged in the board.

For a sample having (estimated to have) voids, the presence of voids in a circled test element group (TEG) of four TSVs in the lower right portion is detected. In such a case, it can be estimated that voids are also present in other TSVs that do not belong to the TEG (here, a plurality of TSVs systematically arranged at a pitch of 40 μm±20 μm).

For a sample having (estimated to have) no voids, an image does not show the presence of voids in a circled test element group (TEG) of four TSVs in the upper left portion.

If at least one TSV belonging to a test element group (TEG) is set so as to have a diameter smaller than that of each of the other TSVs not belonging to the TEG, the criterion for the TEG can be stricter.

For example, with this inspection method using a TEG, to avoid a 100% inspection, in addition to a TSV having the same diameter as that of an active TSV, a TSV having a diameter smaller by, for example, approximately 10%, 20%, or 40% can be formed in the TEG at the same time.

If there is a plurality of TSVs belonging to the test element group (TEG) and the TSVs are arranged at a pitch narrower than that at which other TSVs that do not belong to the TEG are arranged, the criteria for the TEG can be stricter.

For example, in terms of the density of TSVs, in addition to TSVs arranged at the same pitch as the minimum pitch of active TSVs, TSVs arranged at a pitch smaller by, for example, 10% or 20% are formed at the same time.

An example of a location in which the TEG is (independently) arranged can be at least one location in a chip surface. In particular, in the case of a wafer in which neighboring chips have different TSV patterns, one or more locations on each of both sides of the border between the different chips can be used in consideration of differences in plating rates resulting from the arrangement of the chips in the wafer surface.

A specific numerical example can be one in which other TSVs that do not belong to a test element group (TEG) have a diameter of 25 μ,±10 μm and are arranged at a pitch of 40 μm±20 μm. In a board, TSVs can have predetermined diameters and be arranged at predetermined pitches, so the TSVs can have different diameters and be arranged at different pitches. To uniformly form substantially the same TSVs, the diameter dimension tends to be more affected by an etching process condition (exposure condition) than the pitch dimension and is apt to vary.

A specific numerical example can be one in which at least one TSV belonging to a test element group (TEG) has a diameter of 15 μm to 20 μm±10 μm and a probe from Sonoscan Inc. having a high numerical aperture (NA) and having a high resolving power of 230 MHz to 400 MHz is used in ultrasound scanning.

Estimating that a void is present in another TSV that does not belong to a TEG on the basis of a result of a scanning step can be estimating that a void is present in another TSV only if an echo having a strength exceeding a predetermined threshold is detected.

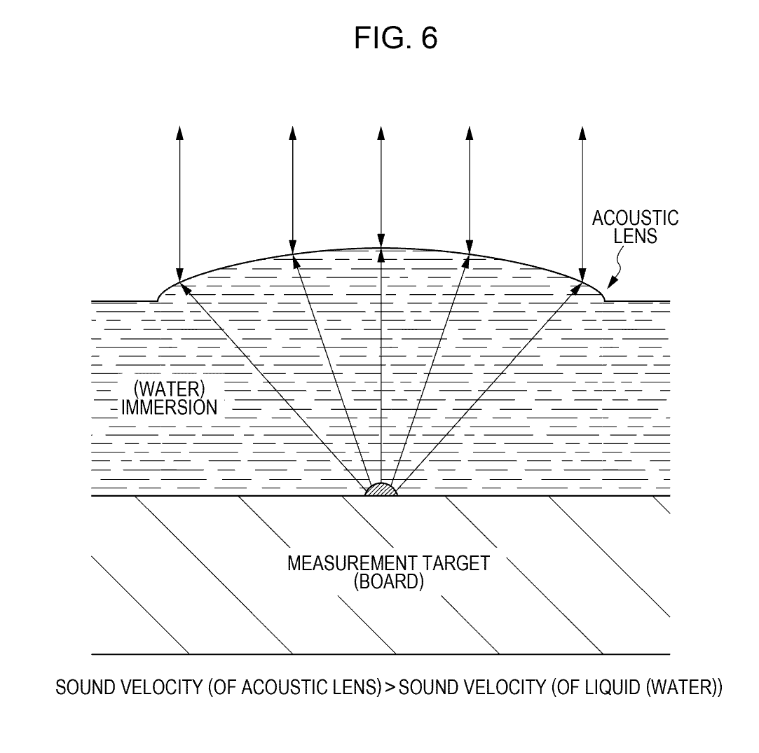

FIG. 6 is an illustration for describing a principle of focusing an ultrasonic wave on a board using an acoustic lens. Focusing effects similar to those of an acoustic lens are obtainable by summing outputs of detection devices arranged in an array through an electrically appropriate delay line (phased array), as illustrated in FIG. 9 described below.

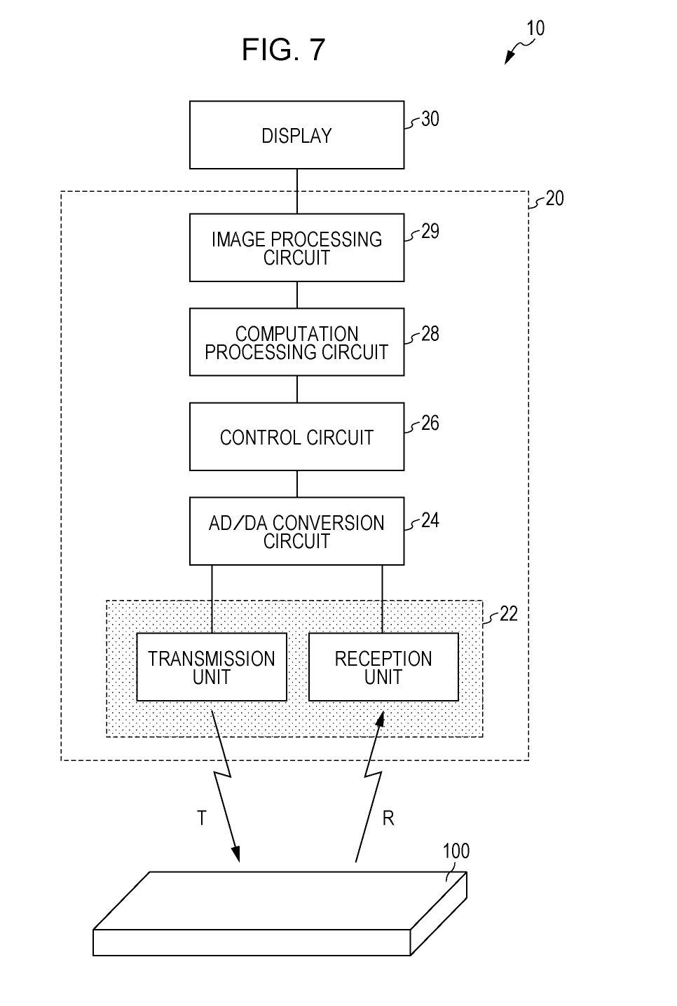

FIG. 7 is a block diagram of an ultrasonic reading system 10 including an ultrasonic reader 20 as the main component.

A transmission unit is disposed so as to transmit an ultrasonic wave through a representative surface 22, the ultrasonic wave is reflected from a board 100, and a reception unit is disposed so as to receive an echo of the ultrasonic wave through the representative surface 22. The transmission unit and the reception unit are connected to an AD/DA conversion circuit 24. The AD/DA conversion circuit 24 is connected to a control circuit 26. The control circuit 26 is connected to a computation processing circuit 28. The computation processing circuit 28 is connected to an image processing circuit 29. The image processing circuit 29 is connected to a display 30.

For example, when scanning is performed over the two-dimensional range (board surface) of the board 100, information about the depth direction can be separately obtained by the use of the control circuit 26. The computation processing circuit 28 can compare a state of reception of an ultrasonic wave in the two-dimensional range (board surface) having a certain depth dimension and a state of an ultrasonic wave in the two-dimensional range having a depth dimension different from the certain depth dimension.

When a result of the comparison is displayed on the display 30, for example, a cathode-ray tube (CRT), a liquid crystal display (LCD), or a plasma display, a state in which reflections of a ultrasonic wave are different can be visualized by, for example, density levels proportional to the amplitudes of echoes of the ultrasonic wave. Which of the AD/DA conversion circuit 24, control circuit 26, computation processing circuit 28, and image processing circuit 29 are included in the ultrasonic reader 20 illustrated in FIG. 7 can be designed by those skilled in the art.

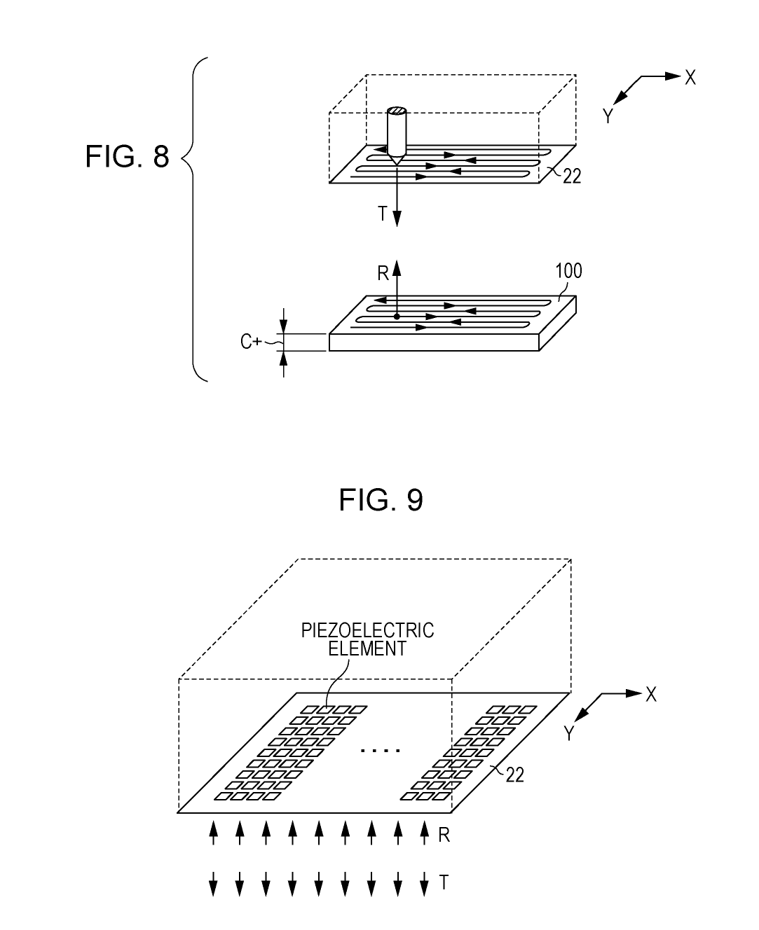

FIG. 8 is a schematic diagram that illustrates scanning using a single probe. An ultrasonic wave having directivity indicated by the arrow T is transmitted from the tip of a single probe, and the ultrasonic wave is reflected from the board 100, as indicated by the arrow R.

Scanning illustrated in FIG. 8 was used as a demonstration experiment. Scanning one-dimensionally in the X direction while moving in the Y direction is performed on a sample with a beam of (as the main component) an ultrasonic wave of 230 MHz to 400 MHz narrowed by, for example, an acoustic lens using a scanning acoustic microscope (SAM) and repeating transmission of an ultrasonic wave and reception of an echo enable successful analysis of the structure of the board 100 in the depth direction with a high resolving power.

FIG. 9 is a schematic diagram that illustrates an ultrasonic reception unit achieved by an array of piezoelectric elements. In place of an electrostrictive vibrator, such as a piezoelectric vibrator (e.g., quartz), a magnetostrictive vibrator and other vibrators can be used.

Two-dimensional reception of an echo of an ultrasonic wave can be achieved by the use of an array of piezoelectric elements. This can also be achieved by the use of electroacoustic transducer elements arranged in an array and controlling the phase of an ultrasonic driving wave applied to each element. This method is called a phased array technique. Typically, an ultrasonic wave is detected by an element that converts vibration to voltage, such as a piezoelectric element. Focusing effects similar to those of an acoustic lens are obtainable by summing outputs of detection devices arranged in an array through an electrically appropriate delay line.

A specific piezoelectric element can have been selected so as to be assigned to a TSV belonging to a TEG. It can be able to be made while a change is flexibly made, as a mechanical processing step or operation, such as automatic selection as an apparatus.

According to the second property of ultrasound, an ultrasonic wave moves from a propagation medium transmitted (to that location), such as liquid or air, to a board. Thus measuring, at the location of each TSV, the length of time from transmission of an ultrasonic wave from the ultrasonic reader 20 to the return of an echo of the ultrasonic wave enables determining the presence of a void, the depth dimension thereof, and the volume thereof. This principle is also known as a pulse-echo technique.

The details of a method for scanning over a board surface, for example, the scanning direction, the number of scans, and the number of retries of scanning, can be designed in advance.

The depth of scanning and the resolution with which scanning can be made are closely related to the frequency of an ultrasonic wave used in scanning. If an ultrasonic wave with a high frequency is used, a high resolution resulting from a high resolving power is obtained, but the scanning cannot reach a deep portion. It is conceivable that, if an aluminum layer (portion) that covers TSVs belonging to a TEG is set thinner, detection of a void will be facilitated.

The present invention is described above using, as an example, a through silicon via (TSV). The present invention is also widely applicable to one in which silicon is replaced with another semiconductor, such as gallium arsenide, gallium phosphide, germanium alone, or silicon germanium. In this respect, the significance of the term “through silicon via (TSV)” should be broadly interpreted.

We claim:

1. A method for estimating a presence of a void in a through silicon via (TSV) on the basis of ultrasound scanning, the method comprising:
preparing a board in which a plurality of TSVs are arranged;
selecting one or more TSVs belonging to a test element group (TEG) from among the plurality of TSVs, wherein physical obstruction in a vicinity of the TEG being less than the physical obstruction in a vicinity of other TSVs that do not belong to the TEG in scanning over a board surface;
scanning at least one of the one or more TSVs belonging to the TEG over the board surface; and
estimating that a void is present in the other TSVs not belonging to the TEG on the basis of a result of the scanning.

2. The method according to claim 1, wherein the physical obstruction in the vicinity of the other TSVs not belonging to the TEG comprises a solder bump.

3. The method according to claim 2, wherein an aluminum or copper pad covering the board is further disposed below the solder bump.

4. The method according to claim 1, wherein the one or more TSVs belonging to the TEG comprises a plurality of TSVs, and the plurality of TSVs are arranged at a pitch narrower than a pitch of the other TSVs not belonging to the TEG.

5. The method according to claim 1, wherein at least one of the one or more TSVs belonging to the TEG has a diameter smaller than a diameter of each of the other TSVs not belonging to the TEG.

6. The method according to claim 1, wherein the other TSVs not belonging to the TEG have a diameter of 25 μm±10 μm and are arranged at a pitch of 40 μm±20 μm.

7. The method according to claim 6, wherein at least one of the one or more TSVs belonging to the TEG has a diameter of 15 μm to 20 μm±10 μm, and an ultrasonic wave for use in ultrasound scanning has a main component of 230 MHz to 400 MHz.

8. A board comprising:
a plurality of through silicon vias (TSVs) which are arranged to estimate a presence of a void in the TSVs, wherein one or more TSVs belonging to a test element group (TEG) are selected from among the plurality of TSVs; and
physical obstruction in a vicinity of the one or more TSVs being less than the physical obstruction in a vicinity of other TSVs not belonging to the TEG in scanning on a board surface.

9. The board according to claim 8, wherein the physical obstruction in the vicinity of the other TSVs not belonging to the TEG comprises a solder bump, and
an aluminum or copper pad covering the board is further disposed below the solder bump.

10. The board according to claim 8, wherein the TEG is disposed in the board independently of the other TSVs arranged in the board.

11. An apparatus for estimating a presence of a void in a through silicon via (TSV) on the basis of ultrasound scanning comprising:
a display;
an imaging processing unit;
a computation processing unit;
a control circuit;
an AD/DA conversion unit;
a transmission unit;
a receiving unit;
a prepared board in which a plurality of TSVs are arranged, wherein one or more TSVs belonging to a test element group (TEG) from among the plurality of TSVs, and physical obstruction in a vicinity of the TEG being less than physical obstruction in a vicinity of other TSVs that do not belong to the TEG in scanning over a board surface.

12. The apparatus according to claim 11, wherein the prepared board includes an aluminum or copper pad covering at least one of the one or more TSVs belonging to the TEG.

13. The apparatus according to claim 11, wherein the physical obstruction in the vicinity of the other TSVs not belonging to the TEG comprises a solder bump.

14. The apparatus according to claim 11, wherein the one or more TSVs belonging to the TEG comprises a plurality of TSVs, and the plurality of TSVs are arranged at a pitch narrower than a pitch of the other TSVs not belonging to the TEG.

15. The apparatus according to claim 11, wherein the other TSVs not belonging to the TEG have a diameter of 25 μm±10 μm and are arranged at a pitch of 40 μm±20 μm.

16. The apparatus according to claim 11, wherein at least one of the one or more TSVs belonging to the TEG has a diameter of 15 μm to 20 μm±10 μm, and an ultrasonic wave for use in ultrasound scanning has a main component of 230 MHz to 400 MHz.
